(19) United States
(12) Patent Application Publication
(10) Pub. No.: US 2026/0157154 A1
(43) Pub. Date: Jun. 4, 2026

(54) SYSTEM AND METHOD TO OPTIMIZE FINAL TESTS WITH A THREE-STAGE MACHINE LEARNING APPROACH USING WAFER TEST DATA

(71) Applicant: Teradyne, Inc., North Reading, MA (US)

(72) Inventors: Katie Monroe, Medford, MA (US); Jin Yu, Lexington, MA (US)

(73) Assignee: Teradyne, Inc., North Reading, MA (US)

(21) Appl. No.: 18/969,112

(22) Filed: Dec. 4, 2024

(51) Int. Cl. H01L 21/66

(52) U.S. Cl. CPC H10P 74/207

(57) ABSTRACT

The disclosure describes semiconductors test systems and related methods for performing semiconductor die final testing. Semiconductor dies may be tested in at least two stages: wafer tests and final die tests. The systems and methods of the disclosure reduce the amount of final die tests that are performed on semiconductor dies, using data from the wafer tests. A semiconductor test system may include a test probe to collect wafer test data from wafers each having a plurality of dies. The dimensionality of the wafer test data may be reduced, and the dies may may be clustered into die clusters using the dimensionally reduced data. Each die cluster may be clustered based on a likelihood that the cluster includes a failed die. The die clusters may be refined into smaller die clusters. Optionally, the smaller die clusters may be used to select at least some dies for final die testing.

### BACKGROUND

### Field

The present application relates to semiconductor wafer and die testing.

### Related Art

During semiconductor fabrication processes, semiconductor wafers and the dies thereon may be tested in at least two stages: wafer tests and final die tests.

### BRIEF SUMMARY

According to aspects of the disclosure, there is provided a method of semiconductor die final testing, comprising: reducing, using at least one processor, dimensionality of wafer test data for one or more wafers using principal component analysis, the one or more wafers having a first plurality of dies disposed thereon; generating, using the at least one processor, a first plurality of die clusters of the first plurality of dies, using the dimensionally reduced wafer test data; classifying, using the at least one processor, with a classification model, each die cluster of the first plurality of die clusters based on a likelihood of the die cluster including a failed die; and refining, using the at least one processor, with a graphic model, the first plurality of die clusters into a second plurality of die clusters, the second plurality of die clusters being smaller than the first plurality of die clusters.

In some embodiments, the method further comprises receiving, using the at least one processor, the wafer test data for the one or more wafers, the wafer test data representing test results of functionality tests performed on the first plurality of dies; reducing the dimensionality of the wafer test data for the one or more wafers using principal component analysis comprises reducing the wafer test data to a set of principal components; the method further comprises determining, using the at least one processor, one or more spatial scores for dies of the first plurality of dies, the one or more spatial scores including one or more of: a first spatial score indicating a spatial position of a die on the one or more wafers; or a second spatial score indicating failures of dies neighboring a die; generating the first plurality of die clusters of the first plurality of dies using the dimensionally reduced wafer test data comprises clustering the first plurality of dies into the first plurality of die clusters based on the set of principal components and the one or more spatial scores; classifying, with the classification model, each die cluster of the first plurality of die clusters based on the likelihood of the die cluster including a failed die comprises labeling each die cluster of the first plurality of die clusters with a die failure label selected from a plurality of die failure labels, the plurality of die failure labels including: a first die failure label indicating a first likelihood of a die cluster including a failed die; and a second die failure label indicating a second likelihood of a die cluster including a failed die, the second likelihood higher than the first likelihood; refining, with the graphic model, the first plurality of die clusters into the second plurality of die clusters comprises: selecting a second plurality of dies from the first plurality of dies by excluding, from the second plurality of dies, die clusters of the first plurality of die clusters having the first die failure label; re-clustering the second plurality of dies into the second plurality of die clusters; and the method further comprises selecting, using the at least one processor, at least some dies of the second plurality of dies as candidates for additional testing, based on the second plurality of die clusters.

In some embodiments, the method further comprises, prior to collecting the wafer test data for the one or more wafers, fabricating the one or more wafers having the first plurality of dies disposed thereon.

In some embodiments, the method further comprises performing final testing on the at least some dies of the second plurality of dies comprising the candidates.

In some embodiments, reducing the wafer test data to a set of principal components comprises reducing dimensionality of the wafer test data to the set of principal components based on variation of the wafer test data.

In some embodiments, determining one or more spatial scores for dies of the first plurality of dies comprises: generating the first spatial score as an edge proximity score indicating distance from a die to a nearest edge of a wafer upon which the die is disposed; and generating the second spatial score as a neighborhood score indicating failures of dies neighboring a die, the failures being weighted based on a distance from the die to failed dies.

In some embodiments, clustering, using the at least one processor, the first plurality of dies into a first plurality of die clusters based on the set of principal components and the one or more spatial scores comprises moving dies between clusters based on a minimum cluster size and a maximum cluster size.

In some embodiments, the method further comprises: labeling, using the at least one processor, each die cluster of the second plurality of die clusters with a die failure label selected from the plurality of die failure labels; selecting, using the at least one processor, a third plurality of dies from the second plurality of dies by excluding, from the third plurality of dies, die clusters of the second plurality of die clusters having the first die failure label; and re-clustering, using the at least one processor, the third plurality of dies into a third plurality of die clusters, an average size of the third plurality of die clusters being smaller than an average size of the second plurality of die clusters.

According to aspects of the disclosure, there is provided at least one non-transitory computer-readable storage medium having instructions encoded thereon that, when executed by at least one processor, cause the at least one processor to perform a method of semiconductor die final testing, the method comprising: reducing dimensionality of wafer test data for one or more wafers using principal component analysis, the one or more wafers having a first plurality of dies disposed thereon; generating a first plurality of die clusters of the first plurality of dies, using the dimensionally reduced wafer test data; classifying, with a classification model, each die cluster of the first plurality of die clusters based on a likelihood of the die cluster including a failed die; and refining, with a graphic model, the first plurality of die clusters into a second plurality of die clusters, the second plurality of die clusters being smaller than the first plurality of die clusters.

In some embodiments, the method further comprises receiving the wafer test data for the one or more wafers, the wafer test data representing test results of functionality tests performed on the first plurality of dies; reducing the dimensionality of the wafer test data for the one or more wafers using principal component analysis comprises reducing the wafer test data to a set of principal components; the method further comprises determining one or more spatial scores for dies of the first plurality of dies, the one or more spatial scores including one or more of: a first spatial score indicating a spatial position of a die on the one or more wafers; or a second spatial score indicating failures of dies neighboring a die; generating the first plurality of die clusters of the first plurality of dies using the dimensionally reduced wafer test data comprises clustering the first plurality of dies into the first plurality of die clusters based on the set of principal components and the one or more spatial scores; classifying, with the classification model, each die cluster of the first plurality of die clusters based on the likelihood of the die cluster including a failed die comprises labeling each die cluster of the first plurality of die clusters with a die failure label selected from a plurality of die failure labels, the plurality of die failure labels including: a first die failure label indicating a first likelihood of a die cluster including a failed die; and a second die failure label indicating a second likelihood of a die cluster including a failed die, the second likelihood higher than the first likelihood; refining, with the graphic model, the first plurality of die clusters into the second plurality of die clusters comprises: selecting a second plurality of dies from the first plurality of dies by excluding, from the second plurality of dies, die clusters of the first plurality of die clusters having the first die failure label; re-clustering the second plurality of dies into the second plurality of die clusters; and the method further comprises selecting at least some dies of the second plurality of dies as candidates for additional testing, based on the second plurality of die clusters.

In some embodiments, the method further comprises, prior to collecting the wafer test data for the one or more wafers, fabricating the one or more wafers having the first plurality of dies disposed thereon.

In some embodiments, the method further comprises performing final testing on the at least some dies of the second plurality of dies comprising the candidates.

In some embodiments, reducing the wafer test data to a set of principal components comprises reducing dimensionality of the wafer test data to the set of principal components based on variation of the wafer test data.

In some embodiments, determining one or more spatial scores for dies of the first plurality of dies comprises: generating the first spatial score as an edge proximity score indicating distance from a die to a nearest edge of a wafer upon which the die is disposed; and generating the second spatial score as a neighborhood score indicating failures of dies neighboring a die, the failures being weighted based on a distance from the die to failed dies.

In some embodiments, clustering the first plurality of dies into a first plurality of die clusters based on the set of principal components and the one or more spatial scores comprises moving dies between clusters based on a minimum cluster size and a maximum cluster size.

In some embodiments, the method further comprises: labeling each die cluster of the second plurality of die clusters with a die failure label selected from the plurality of die failure labels; selecting a third plurality of dies from the second plurality of dies by excluding, from the third plurality of dies, die clusters of the second plurality of die clusters having the first die failure label; and re-clustering the third plurality of dies into a third plurality of die clusters, an average size of the third plurality of die clusters being smaller than an average size of the second plurality of die clusters.

According to aspects of the disclosure, there is provided a semiconductor wafer test system comprising: at least one processor; and at least one non-transitory computer-readable storage medium having instructions encoded thereon that, when executed by the at least one processor, cause the at least one processor to perform a method comprising: reducing dimensionality of wafer test data for one or more wafers using principal component analysis, the one or more wafers having a first plurality of dies disposed thereon; generating a first plurality of die clusters of the first plurality of dies, using the dimensionally reduced wafer test data; classifying, with a classification model, each die cluster of the first plurality of die clusters based on a likelihood of the die cluster including a failed die; and refining, with a graphic model, the first plurality of die clusters into a second plurality of die clusters, the second plurality of die clusters being smaller than the first plurality of die clusters.

In some embodiments, the semiconductor wafer test system further comprises at least one semiconductor test probe configured to collect the wafer test data for the one or more wafers, the wafer test data representing test results of functionality tests performed on the first plurality of dies; reducing the dimensionality of the wafer test data for the one or more wafers using principal component analysis comprises reducing the wafer test data to a set of principal components; the method further comprises determining one or more spatial scores for dies of the first plurality of dies, the one or more spatial scores including one or more of: a first spatial score indicating a spatial position of a die on the one or more wafers; or a second spatial score indicating failures of dies neighboring a die; generating the first plurality of die clusters of the first plurality of dies using the dimensionally reduced wafer test data comprises clustering the first plurality of dies into the first plurality of die clusters based on the set of principal components and the one or more spatial scores; classifying, with the classification model, each die cluster of the first plurality of die clusters based on the likelihood of the die cluster including a failed die comprises labeling each die cluster of the first plurality of die clusters with a die failure label selected from a plurality of die failure labels, the plurality of die failure labels including: a first die failure label indicating a first likelihood of a die cluster including a failed die; and a second die failure label indicating a second likelihood of a die cluster including a failed die, the second likelihood higher than the first likelihood; refining, with the graphic model, the first plurality of die clusters into the second plurality of die clusters comprises: selecting a second plurality of dies from the first plurality of dies by excluding, from the second plurality of dies, die clusters of the first plurality of die clusters having the first die failure label; re-clustering the second plurality of dies into the second plurality of die clusters; and the method further comprises selecting at least some dies of the second plurality of dies as candidates for additional testing, based on the second plurality of die clusters.

In some embodiments, the at least one semiconductor test probe is further configured to perform final testing on the at least some dies of the second plurality of dies comprising the candidates.

In some embodiments, reducing the wafer test data to a set of principal components comprises reducing dimensionality of the wafer test data to the set of principal components based on variation of the wafer test data.

In some embodiments, determining one or more spatial scores for dies of the first plurality of dies comprises: generating the first spatial score as an edge proximity score indicating distance from a die to a nearest edge of a wafer upon which the die is disposed; and generating the second spatial score as a neighborhood score indicating failures of dies neighboring a die, the failures being weighted based on a distance from the die to failed dies.

In some embodiments, clustering the first plurality of dies into a first plurality of die clusters based on the set of principal components and the one or more spatial scores comprises moving dies between clusters based on a minimum cluster size and a maximum cluster size.

In some embodiments, the method further comprises: labeling each die cluster of the second plurality of die clusters with a die failure label selected from the plurality of die failure labels; selecting a third plurality of dies from the second plurality of dies by excluding, from the third plurality of dies, die clusters of the second plurality of die clusters having the first die failure label; and re-clustering the third plurality of dies into a third plurality of die clusters, an average size of the third plurality of die clusters being smaller than an average size of the second plurality of die clusters.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in all the figures in which they appear.

FIG. 1 shows a first process flow for a method of semiconductor die final testing, according to some embodiments;

FIG. 2 is a block diagram of components of a semiconductor test system, according to some embodiments;

FIG. 3 shows a second process flow related to a method of semiconductor die final testing, according to some embodiments;

FIG. 4 shows a third process flow related to a method of semiconductor die final testing, according to some embodiments;

FIG. 5 shows first plots related to performing a method of semiconductor die final testing, according to some embodiments;

FIG. 6 shows second plots related to performing a method of semiconductor die final testing, according to some embodiments;

FIG. 7 shows a fourth process flow related to a method of semiconductor die final testing, according to some embodiments;

FIG. 8 shows third plots related to performing a method of semiconductor die final testing, according to some embodiments;

FIG. 9 is an example block diagram of a special purpose computer system that can be configured to execute the functions discussed herein;

FIG. 10 is a block diagram of functional blocks of a semiconductor test system, according to some embodiments.

### DETAILED DESCRIPTION

The disclosure describes semiconductors test systems and related methods for performing semiconductor die final testing. Semiconductor dies may be tested in at least two stages: wafer tests and final die tests. The systems and methods of the disclosure reduce the amount of final die tests that are performed on semiconductor dies, using data from the wafer tests. A semiconductor test system may include a test probe to collect wafer test data from wafers each having a plurality of dies. The dimensionality of the wafer test data may be reduced, and the dies may may be clustered into die clusters using the dimensionally reduced data. Each die cluster may be clustered based on a likelihood that the cluster includes a failed die. The die clusters may be refined into smaller die clusters. Optionally, the smaller die clusters may be used to select at least some dies for final die testing.

According to aspects of the disclosure, there is provided semiconductor test systems and related methods that perform methods related to semiconductor die final testing. In order to reduce a number of dies upon which final testing is performed, the systems and methods described herein cluster the dies, classify the clusters, and refine the clusters of dies into smaller groups, and thereby identify potential failures in semiconductor manufacturing processes. In some embodiments, the techniques described herein provide a granular level of detail in semiconductor die failure by providing smaller, more defined clusters of dies, which provides for detection of subtle discrepancies in the dies, and determination that such discrepancies may indicate faults in the dies. Furthermore, the systems and methods break down larger groups of dies into smaller, more refined groups, allowing for deeper analysis of dies and dies groups, providing for identification of failures with greater precision and specificity.

According to some embodiments, wafer testing (WT), includes checking each die on a semiconductor wafer for basic functionality using probe cards. Wafer testing is performed before dies are cut and packaged. Dies that pass wafer testing may be marked as good and may be advanced to proceeding steps in the manufacturing process. Those dies that fail wafer testing may be discarded or marked for further analysis. One goal of wafer testing is to identify non-functional chips as early in the manufacturing process as possible in order to reduce effort that is wasted on defective parts. Final testing (FT) is performed after the dies have been cut from the wafer and assembled and/or packaged. Final tests may be performed to check that each die meets operational specifications under various conditions, which may be used to confirm the dies are ready for real-world applications. Final tests often simulate an operating environment of the dies and may be more rigorous and comprehensive than wafer tests. Often times, to ensure that each die can withstand harsh operating conditions, thousands of tests are applied during both the wafer test and final test stages.

The wafer tests and final tests applied to each die by conventional systems greatly increase the cost of the manufacturing process for semiconductor dies. Extensive testing of modern semiconductor dies (which often becomes even more extensive for more complex dies) generates prolonged testing time and contributes to increased costs.

Typical approaches to semiconductor die final testing perform final die testing on all dies, which is costly and time-consuming, especially when most dies pass the tests. Furthermore, some conventional approaches for identifying potential failed dies might include traditional rule-based testing, where dies are evaluated against fixed criteria, or statistical sampling, which tests only a subset of dies to infer the quality of the entire batch. One rule-base approach, adaptive testing, attempts to tailor the testing process based on real-time feedback. For instance, in the final test phase, the process may start with a set of base test items. Based on the outcomes of these initial tests, a set of subsequent tests is selected to try to confirm the die's readiness for end-use. This rule-based approach attempts to streamline testing, but such a technique has limitations in flexibility, scalability, maintenance. Because this approach requires predefined rules, this approach fails adapt to unexpected scenarios, and maintaining and updating rules is costly and complex, which limits the scalability of the technique, particularly as die complexity increases. Furthermore, the initial step of creating an effective rule set depends heavily on having accurate expert knowledge, which can pose risks if key personnel are unavailable or mistaken. Furthermore, this approach fails to make use of the large information set already available in wafer test data.

By nature, semiconductor wafer and die test data has only small variations between different wafers and dies. These small variations make it difficult for conventional methods to identify potential die failures. In contrast, the techniques described herein provide dynamic and adaptive clustering, providing more accurate identification of potential failures and fewer overlooked failures or false negatives. For example, due to these small variations, when wafer test data of a die is used to predict the final test pass or fail of the same die, accuracy is very low. In one exemplary dataset, the number of dies that pass in final test is 2,066,514 and the number that fail is 2,186. Initial classification results on different models might provide very high accuracy when classifying passing dies, but very low accuracy when classifying if a die has failed in final testing. Sampling (e.g., oversampling, under sampling) and class imbalance (e.g., cost-sensitive learning, ensemble methods, class weight adjustment) techniques may be ineffective due to the high similarity between classes. Furthermore, mutual information tests conducted between wafer test and final test data shows a weak correlation for the same die, explaining why predicting a final test pass or fail for individual die using wafer test data is not effective.

According to aspects of the disclosure, a semiconductor test system performs a clustering approach for final die testing that provides several improvements. The systems described herein provide increased testing precision and provide predictive insights into die failures. These systems perform machine learning techniques, including node embeddings within a kNN graphical model. Accordingly, the systems described herein provide improved failure detection and also predict potential faults, in order to allow for proactive interventions. The semiconductor test systems describe herein thereby provide efficient use of resources (such as efficient use of semiconductor test probes for final tests), reducing unnecessary testing and allowing testing efforts to be focused on higher-risk areas. As such, the systems described herein perform methods that enhance the efficacy and efficiency of the final test phases in semiconductor production in modern semiconductor manufacturing environments.

According to some embodiments, the systems described herein utilize wafer test data to predict whether a cluster of dies will have failure or not in final test. These clustering and prediction techniques provide improvements in semiconductor manufacturing. The predictions performed by the semiconductor test systems described herein provide for early detection of potential faults in semiconductor dies, which reduces the likelihood of defective dies reaching later or final stages of production. The systems may also perform these predictions to identify patterns and anomalies in dies that correlate with die failures, which may be uses in to proactively implement quality control measures. Accordingly, the semiconductor test systems described herein provide improved semiconductor die yield rates, reduced costs (e.g., costs associated with rework and scrap of semiconductor dies) and enhanced overall reliability of the semiconductor products. Furthermore, the systems may perform predictions to reduce the time cycle of a testing process, providing form improved resource allocation and accelerated time-to-market for new semiconductor technologies.

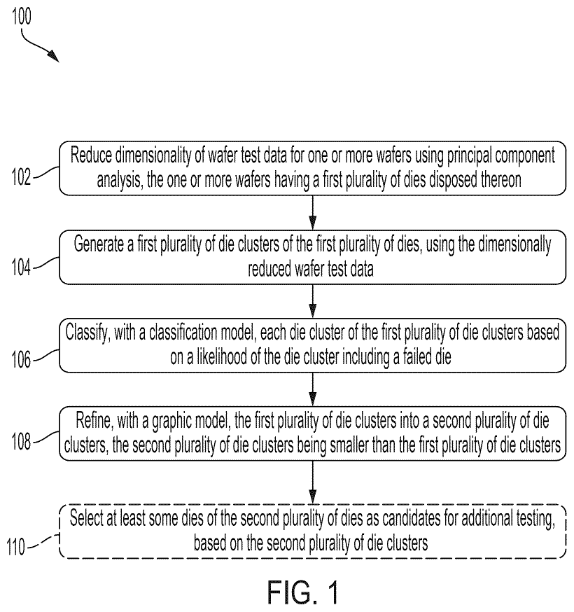

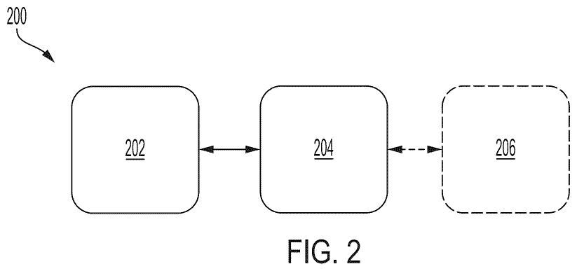

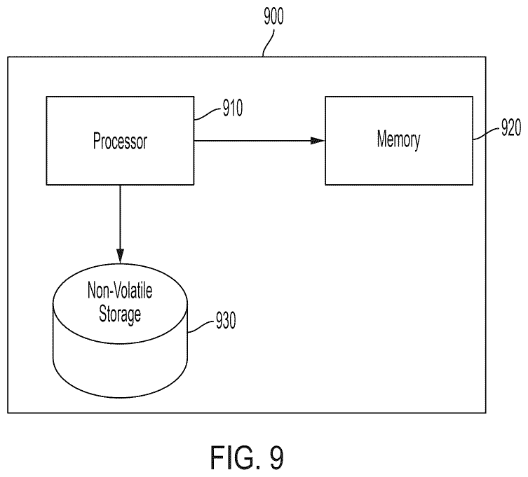

FIG. 1 shows a first process flow 100 for a method of semiconductor die final testing, according to some embodiments and FIG. 2 is a block diagram of components of a semiconductor test system 200, according to some embodiments. Components of the semiconductor test system 200 may perform the first process flow 100. The semiconductor test system 200 includes at least one special purpose computer system 202, at least one semiconductor test probe 204, and optionally, at least one semiconductor fabrication device 206. One embodiment of a special purpose computer system 900 (which may be an implementation of special purpose computer system 202) is described in more detail below with respect to FIG. 9. The components of the semiconductor test system 200, including the at least one special purpose computer system 202, the at least one semiconductor test probe 204, and the at least one semiconductor fabrication device 206 may be located in different facilities, or may also be located in a single facility. When components are located in different facilities, semiconductor wafers and dies may be transported between the facilities for different testing and fabrication steps.

First process flow 100 comprises step 102, step 104, step 106, step 108 and may also include optional step 110. The semiconductor test system 200 may perform the first process flow 100 using the at least one special purpose computer system 202, such as by using at least one processor of the at least one special purpose computer system 202. At step 102, the semiconductor test system 200 reduces dimensionality of wafer test data for one or more wafers using principal component analysis, where the one or more wafers has a first plurality of dies disposed thereon. At step 104, the semiconductor test system 200 generates a first plurality of die clusters of the first plurality of dies using the dimensionally reduced wafer test data. At step 106, the semiconductor test system 200 classifies, with a classification model, each die cluster of the first plurality of die clusters based on a likelihood of the die cluster including a failed die. At step 108, the semiconductor test system 200 refines, with a graphic model, the first plurality of die clusters into a second plurality of die clusters, the second plurality of die clusters being smaller than the first plurality of die clusters. Optionally, at step 110, the semiconductor test system 200 selects at least some dies of the second plurality of dies as candidates for additional testing, based on the second plurality of die clusters. Aspects related to the first process flow 100 are now described in more detail.

In some embodiments, the semiconductor test system 200 may also fabricate the one or more wafers by forming a plurality of dies on the wafers. The fabrication step may be performed using the at least one semiconductor fabrication device 206, and it may be performed prior to collecting the wafer test data for the one or more wafers.

As described above, the semiconductor test system 200 may include at least one semiconductor test probe 204. The semiconductor test probe 204 may be configured to collect the wafer test data for the one or more wafers. According to various embodiments, wafer test data may represent various aspects of wafers and the dies formed thereon. For example, in some embodiments, wafer test data may represent results of functionality tests that the at least one semiconductor test probe 204 performs on the wafers and/or dies. In some embodiments, such as when the second plurality of dies are re-clustered into the second plurality of die clusters and at least some dies of the second plurality of dies are selected as candidates for additional testing, the at least one semiconductor test probe 204 may also perform the final die testing on the dies selected for final testing. As described in more detail below, this set of selected dies may be made up of at least some dies of the reduced second plurality of dies.

Turning now to further detail of the first process flow 100 performed by the semiconductor test system 200. Rather than predicting a final test pass or fail for each individual die, semiconductor test systems described herein may perform a multi-stage machine learning method to determine if groups of dies will have failed die.

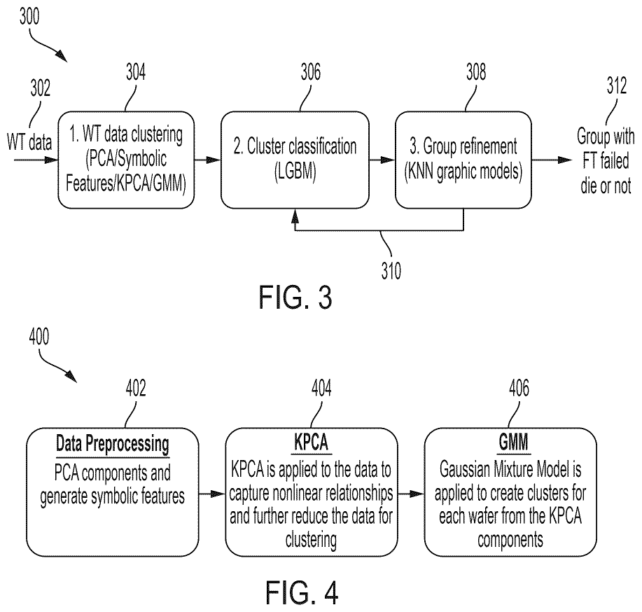

FIG. 3 shows a second process flow 300 related to a method of semiconductor die final testing, according to some embodiments. As shown in FIG. 3, the second process flow 300 has input 302, performs step 304, step 306, and step 308 with feedback loop 310, and has output 312. FIG. 3 illustrates an exemplary embodiment of the multi-stage machine learning method to determine if groups of dies will have failed die. As shown in FIG. 3, the input 302 of the second process flow 300 may be water test data, which may be collected for one or more wafers, each having multiple dies formed thereon. The output 312 of the second process flow 300 is a prediction of a group of dies which will have failed dies in final test.

At step 304 the semiconductor test system may apply Principal Component Analysis (PCA) to reduce the dimensionality of wafer tests. In some embodiments, there may be (>800 wafer test items), and the PCA may be applied to 8 principal components. Additionally, one or more spatial scores representing symbolic features of dies may be generated. These scores may include scores such as a weighted neighborhood score, among others, which is described in more detail below. The principal components and the symbolic features may be provided as input to Kernal Principal Component Analysis (KPCA), which may generate and output a set of further reduced components for the clustering, such as two or three components. The semiconductor test system may perform a General Mixture Model (GMM) clustering method (or another method, such as k-means, DBSCAN, or other clustering method) to generate the initial first plurality of die clusters. In some embodiments, the initial set of clusters may include between 20 and 30 clusters, such as 25. The PCA and GMM may include processes to handle missing data and imbalanced clusters. These clustering algorithms (general mixture models, balanced general mixture models, K-means) may therefore divide the dies into groups with the KPCA being used to capture non-linear and other complex relationships in wafer test data to generate components ready for clustering.

At step 304, the semiconductor test system may classify the clusters by labeling each cluster with a die cluster label. For example, labels may be applies using a Light Gradient Boosting Machine (LGBM) model classify the groups of dies into classes. Each class may have a label that indicates whether the class has failed die or not, that indicates a likelihood that the class has a failed die. During step 304, each cluster might still have a large number of dies where only a small portion of these dies might fail. The techniques used in step 304 may be supervised learning techniques, and the LGBM model or other model may be trained to identify groups of die that are more likely to contain failures in final test. Classification models may be trained on the cluster features (cluster size, density, variance, skew, etc.) to classify if a cluster contains failures. Models and training are discussed in additional detail below.

Furthermore, the process may perform multiple iterations of clustering and generating cluster features for training the LGBM model. For example, wafer features may be generated from the first iteration to the second iteration. In some embodiments, the first iteration creates a data frame of cluster features for each cluster for each of the wafers (which may be, for example, 25 wafers). In a second iteration, the process may repeat KPCA and GMM steps on these clusters to generate the features for training the LGBM model. Additionally, this process may be repeated for a third iteration or for a greater number of iterations. As such, following a second iteration of die cluster, cluster features may be generated from this second clustering.

When clustering and feature generation steps are completed, the process may move to the LGBM classification. At least some of the cluster features generated from the clusters of the various iterations may be used for training the LGBM.

At step 306, the semiconductor test system refines the first plurality of clusters into a second plurality of clusters. For example, the semiconductor test system may use a k-Nearest Neighbor (kNN) or other graphical model to refine groups to smaller clusters. As an example, if there are 100 dies per group from step 304, the system may use kNN to further refine that to 5 sub-groups. As a result, the system may identify 4 subgroups with no final test failed dies, and the remaining subgroup may have failed dies. In this way, the system reduces the number of dies that need more attention for actual performance of final testing. Accordingly, by using the kNN or other graphic models, the test system may refine groups of dies that might contain failed final test dies may be into smaller subgroups to improve the prediction granularity and precision of the groups which are labeled as including failures.

At step 308, the test system may refine groups of clusters. For example, some clusters may be excluded from further analysis, and cluster size of remaining clusters may be reduced. Refinement may be performed using kNN graphic models, as described in more detail below with respect to FIG. 7. Furthermore, the test system may use feedback loop 310 to return to step 306 to re-classify any new re-clustered groups of dies generated at step 308.

FIG. 4 shows a third process flow 400 related to a method of semiconductor die final testing, according to some embodiments. The third process flow 400 may show further detail of the step 304 of the second process flow 300. Third process flow 400 shows step 402, step 404, and step 406 for unsupervised learning to divide dies into groups.

At step 402, the semiconductor test system first receives the wafer test data, e.g., by extracting it from compressed IDDS files. Each file may be cleaned and formatted with file identifiers. Data frames from each wafter test insertion (e.g., four, as above) for each wafer test may be merged to combine the data into a single data frame for each wafer. This data frame may be paired with its correct label from the final test data based on generated file identifiers.

At step 402, PCA is used first to transform the data into principal components. In some embodiments, the dimensionality of the wafer test data for the one or more wafers may be reduced to a set of principal components using principal component analysis. The wafer test data may be reduced to the set of principal components based on variation of the wafer test data.

Principal components may be generated to capture a high level or maximum level of variance of the data features. As noted above, the data may be reduced to a set of 6, 8, 10, or another number of principal components to retain a level of data information that is balanced with model effectiveness and performance while by reducing dimensions. The PCA may be performed in iterations to account for missing values in wafer test data. In the step 402,, missing values may be temporarily filled in with column means to provide a complete dataset for the PCA transformation. The data may then be reduced by identifying the principal components to capture significant variance in the data. The data may then be reconstructed to preserve the original column order and data relationships. Missing values may then be updated with reconstructed values from the PCA. Such a transformation may be repeated until the data converges and the imputed values stabilize.

According to some embodiments, semiconductor test systems may also determine one or more spatial scores for dies formed on the wafers. The spatial scores may represent various spatial parameters of the dies. For example, the one or more spatial scores can include a spatial score that indicating a spatial position of a die on the one or more wafers. Spatial position scores are described in more detail below; however, one example includes an edge proximity score that indicating the distance from a die to the nearest edge of a wafer upon which the die is formed. An additional type of spatial score that may be determined is a spatial score that indicates failures of dies neighboring a die. For example, this type of score may be a neighborhood score that indicating failures of dies neighboring a die, where the failures are weighted more or less based on a distance from the die to failed dies, as described in more detail below.

The spatial scores represent symbolic features of the dies. The spatial scores are generated in addition to the reduced principal components for the dies. columns. The symbolic features provide for enhanced interpretability, improved accuracy, and domain specific knowledge in the test system. According to some embodiments, symbolic features may include weighted neighborhood score, edge proximity, neighboring dies with score above a threshold, among other scores.

Weighted neighborhood score is a feature that calculates a neighborhood score for each die in a wafer based on pass or fail results of surrounding die in a particular radius (e.g., a radius of 2, 5, or 10 dies). A Gaussian kernel may be used to compute weights based on distances so that the weight will decrease with distance. The weighted score for each die may be calculated by taking the dot product of the weight's matrix and the numerical values vector. The score may be calculated for each of the wafer tests done on a wafer, as merely one example, one neighborhood score for each of four wafer tests.

Edge proximity is a feature that calculates the proximity of a die to a nearest wafer edge. The distance may be normalized to give a proximity score between 0 and 1, where 1 indicates that the die is on the edge of the wafer and 0 indicates the die is at the center.

Neighboring dies with score above a threshold is a feature that calculates the number of neighboring dies within the radius that have a maximum weighted score above a threshold. In some embodiments, the threshold may be 0.7, 0.8, 0.9, or another value. The neighbors within the radius for each die may be identified and the maximum weighted score for each neighbor may be obtained. The count of how many of these scores exceed the threshold is then determined.

Variance of neighborhood scores is a feature that calculates the variance of the neighborhood scores for each die within the radius. For each die in the slot, the function identifies its neighbors within the radius using the distance matrix and excluding the die itself. The variance of the neighbors is then calculated and returned for each of the wafer tests performed on the wafer.

In some embodiments, the first plurality of die clusters may be generated based on the set of principal components representing the dimensionally reduced wafter test data and also based on the one or more spatial scores. The first plurality of dies may be clustered into the first plurality of die clusters by moving dies between clusters so that the clusters have between a minimum cluster size and a maximum cluster size.

At step 404 KPCA is applied to the output data of step 402 to further reduce the data prior to clustering. The KPCA may be applied to capture nonlinear or other relationships in the PCA and symbolic feature data of step 402.

At step 406, the dies may be clustered into groups of dies. The semiconductor test system may classify the die clusters by labeling each die cluster with a die failure. Each die failure label may indicate a likelihood of a die cluster including a failed die, with various labels indicating a higher or lower likelihood of a die cluster including a failed die. For example, a KPCA and GMM algorithm may be applied on the data of cluster features at steps 404 and 406. In some embodiments, the GMM may be a balanced GMM that extends a standard Gaussian Mixture Model to ensure that clusters fall between a minimum and maximum cluster size. After fitting the Gaussian Mixture Model, the test system may use the balanced GMM to check the size of the clusters and iteratively adjusts them if any cluster if it is smaller than a minimum size or larger than a maximum size. The system may balance cluster size by moving points between clusters: increasing a cluster's size by assigning nearby points from other clusters or decreasing the size by reassigning its furthest points to closer clusters.

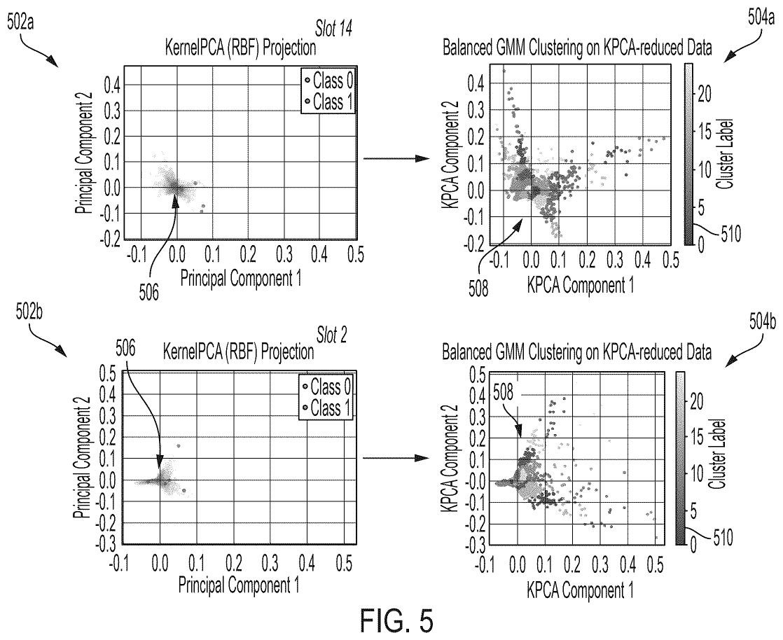

FIG. 5 shows first plots related to performing a method of semiconductor die final testing, according to some embodiments. FIG. 5 shows plots 502a and 504a for slot 14, and plots 502b and 504b for slot 2, with each slot being a different wafer that is tested. Each of plot 502a and 502 be shows failing dies 506 as darker dots with the remaining lighter dots representing passing dies. Plots 504a and 504b include clusters 508 that each have a label 510, represented by a different color. Plots 504a and 504b show the results of clustering using the exemplary of slot 2 and 14. In the example, each die from these wafers is assigned to one of the 25 clusters generated by GMM. It may be appreciated that failing dies may tend to cluster towards the center of the graph in denser areas, with pairs of failed die or single failed die further from the center. In the exemplary embodiment of FIG. 5, the cluster number is set to four, which provides the following cluster labels 510: (1) does not contain failures (second lightest dots); (2) most likely will not contain failures (lightest dots); (3) likely will contain failures (darkest dots); and (4) does contain failures (second darkest dots). In some embodiments, other cluster numbers may be used, each cluster having a label falling along a continuum of die failure probability. For example, in other embodiments, 2, 3, 5, 6, clusters may be used by the system, and each cluster may be applied with a cluster label that indicates a different probability that the die cluster includes failed final test die. While FIG. 5 shows a range of different potential cluster labels 510 falling along a vertical axis, it should be appreciated that, in various embodiments, the die cluster labels used for labeling may a defined set of discrete values, e.g., the set of four discrete values described above. As described herein, the clusters may he classified with methods such as LGBM for further processing.

It should be appreciated unsupervised clustering or other techniques may be iterated on these cluster features that were generated to identify which clusters contain failures. In some embodiments, the semiconductor test system may refine a first plurality of die clusters into the second plurality of die clusters using a graphic model. The semiconductor test system may perform the refining by excluding some of the die clusters of the first plurality of die clusters from the second plurality of dies. Die clusters of the first plurality of die clusters may be selected for exclusion based on their die failure label. For example, die clusters having a die failure label that indicates a lower likelihood of a die cluster including a failed die may be exclude from the second plurality of die clusters.

Furthermore, cluster refinement may be performed in additional iterations. In some embodiments, the semiconductor test system may also label each of the second plurality of die clusters with a die failure label. Then, the semiconductor test system may select a third plurality of dies from the second plurality of dies by excluding some of the second plurality of die clusters that have die failure labels indicating a lower likelihood of including a failed die. Then, the semiconductor test system may re-cluster the remaining dies into a third plurality of die clusters that are smaller still than the second plurality of die clusters.

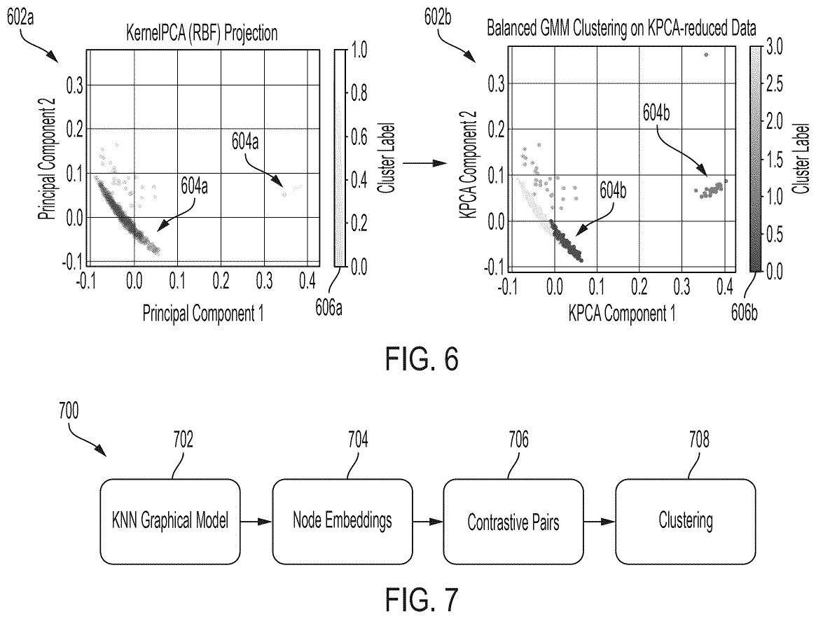

FIG. 6 shows second plots related to performing a method of semiconductor die final testing, according to some embodiments. In FIG. 6, additional iteration is performed on the clusters. FIG. 6 shows plot 602a having clusters 604a with labels 606a and plot 602b having clusters 604b and labels 606b. As shown in FIG. 6, the test system may perform iterative clustering to further separate clusters. With respect to FIG. 6, it may be appreciated that there is a clear separation for some of the die that contain failures. Each dot in FIG. 6 represents a cluster from a wafer. Plot 602a show 625 clusters for 25 wafers total where the lightest dots depict clusters that contain failures, and the darkest dots depict clusters that do not contain failures. Plot 602b shows a refinement with a GMM cluster number set to four: (1) does not contain failures (second lightest dots), (2) most likely will not contain failures (lightest dots), (3) likely will contain failures (darkest dots), and (4) does contain failures (second darkest dots).

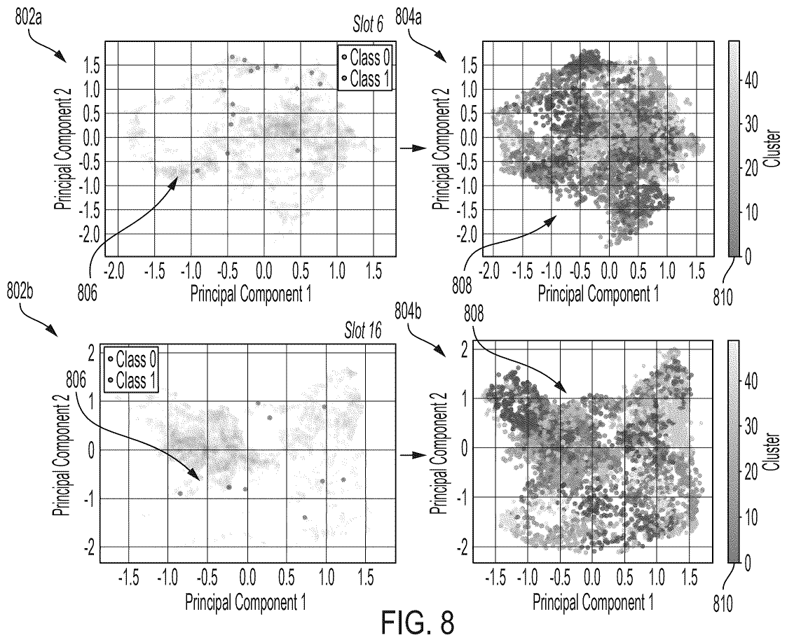

FIG. 7 shows a fourth process flow 700 related to a method of semiconductor die final testing, according to some embodiments. As shown in FIG. 7, test systems described herein may refine the clusters or groups into subgroups to improve prediction precision. The semiconductor test system may provide enhanced precision for clustering and prediction failed final test dies, by performing a combined kNN and graph-based technique. The fourth process flow 700 includes step 702, step 704, step 706, and step 708. At step 702 the test system uses a kNN graphical model to establish a primary clustering of dies based on similarity metrics derived from node embeddings, capturing nuanced relationships and characteristics of each die. At step 704, the test system uses node embeddings, to encapsulate each die's contextual information within the manufacturing process. At step 706, the test system uses contrastive pairs, e.g., pairs of dies with one known to pass and one known to fail, to fine-tune the embeddings, allowing the test system's model to accentuate features that differentiate between passing and failing outcomes. At step 708, the test system clusters the dies. Once initial clusters are formed, the test system may further divide the dies into smaller sub-clusters using additional clustering based on analyzing the refined embeddings. During step 708, the test system may perform an iterative process of clustering and re-clustering, using the graph-based embeddings and contrastive learning, in order to increase the granularity and accuracy of predictions for the likelihood of die failures in final tests. FIG. 8 shows exemplary results generated by a test using the kNN graphical model with node embeddings to enhance the granularity and accuracy of die group. As discussed in additional detail below with respect to FIG. 8, this technique clearly grouping failed dies (shown as Class 1 in darker dots) and forms distinct clusters of failures outside the densest areas, resulting in smaller groups containing the failed die compared with the larger dies groups described with respect to other plots.

FIG. 8 shows third plots related to performing a method of semiconductor die final testing, according to some embodiments. FIG. 8 shows plots 802a and 804a for slot 6, and plots 802b and 804b for slot 16. Each of plot 802a and 802 be shows failing dies 806 as darker dots with the remaining lighter dots representing passing dies as Class 0. Plots 804a and 804b include clusters 808 that each have a label 810, represented by a different color. In the exemplary embodiment of FIG. 8, the cluster number is set to four. In the illustrated embodiment of plots 804a and 804b, there are 50 clusters, but greater or lesser numbers of clusters may be used.

Each cluster in these further plots may be derived from a graphical model to capture similarities of dies that are selected for this further analysis from the previous steps described above. In other words, clusters in plots 804a and 804b indicate similarities of dies. In plots 804a and 804b, the clusters may not correspond directly to likelihood of failure directly at this step, as compared with other plots described above. Rather, the clusters in plots 804a and 804b may be formed in a manner that indicates further patterns in wafer test data. These further clusters and their data patterns may then be used to identify clusters that contain failures by training at least one additional model and/or using the features with specified collected final test data to more accurately identify failure data in these clusters.

Accordingly, it should be appreciated from FIG. 8 that systems and methods described herein may further refine clusters to provide more granular groups of dies, allowing more accurate and precise prediction of failed final test dies. As shown in FIG. 8, the semiconductor test system may use a kNN or other graphical model with node embeddings to further improve the granularity and accuracy for the slots. As shown in FIG. 8, after cluster refinement, plots 802a and 802b show, with darker dots, more clear groupings of the failed dies 806. Plots 804a and 804b, where each color represents one cluster, show more clear clusters of failures that are no longer in the densest areas, with larger clusters leading to smaller groups that provide more specificity. In plots 804a and 804b, on average, one cluster contains about 60 dies, reduced from the plots of prior figures.

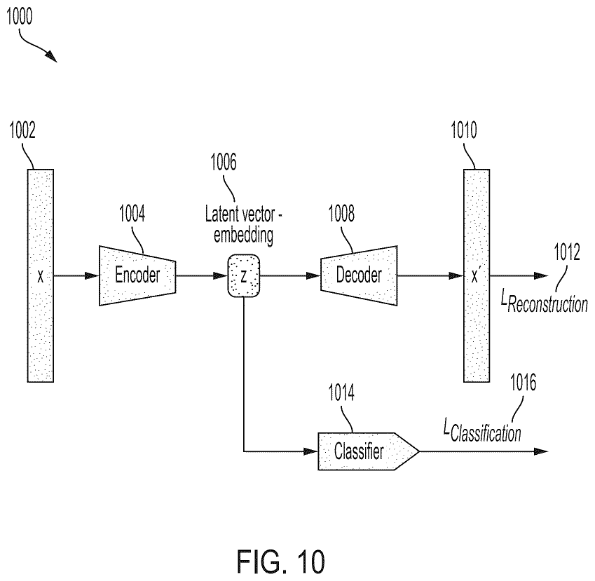

According to some embodiments, an encoder may alternatively be used to generate embeddings rather than the PCA and KPCA techniques described above. FIG. 10 is a block diagram of functional blocks of an autoencoder 1000 for a semiconductor test system, according to some embodiments. As shown in FIG. 10, the autoencoder 1000 may include an input (x) 1002, an encoder 1004, a latent vector embedding (z) 1006, a decoder 1008, an output (x′) 1010, having reconstruction loss (LReconstruction) 1012, a classifier 1014, and having classification loss (LClassification) 1016. A semiconductor test system may train an autoencoder model, and the autoencoder may generate meaningful embeddings using both the wafer test data and the manual features described above (such as the indications of failed neighboring dies). The wafer test data and manual features may be used as the input to the autoencoder and final test pass/fail results may be used as ground truth labels to guide training. The autoencoder may incorporate supervised learning elements. For example, the model may be encouraged to learn embeddings that reconstruct the input data while also capturing patterns associated with final test outcomes. In the example shown in FIG. 10, the total loss (LTotal) may combine the reconstruction loss (LReconstruction) and classification loss (LClassification), with the classification loss may be multiplied by a scaling factor 2. The total loss may be used to compute gradients to train the model. In the example of FIG. 10, these embeddings represent each die in a lower-dimensional space that represents information for quality assessment. After training, the semiconductor die test system may use the embeddings to cluster the dies into small groups based on similarity, which may separate groups with failed dies from those without. Dies clustered into groups predicted to have no failures may then bypass the final testing stage, which may improve the efficiency of testing workflow and reduce resource expenditure.

An illustrative implementation of a computer system 900 that may be used in connection with any of the embodiments of the disclosure provided herein is shown in FIG. 9. The computer system 900 may include one or more processors 910 and one or more articles of manufacture that comprise non-transitory computer-readable storage media (e.g., memory 920 and one or more non-volatile storage media 930). The processor 910 may control writing data to and reading data from the memory 920 and the non-volatile storage device 930 in any suitable manner. To perform any of the functionality described herein, the processor 910 may execute one or more processor-executable instructions stored in one or more non-transitory computer-readable storage media (e.g., the memory 920), which may serve as non-transitory computer-readable storage media storing processor-executable instructions for execution by the processor 910.

A semiconductor test system may process wafer test data (and reduced versions thereof) and symbolic features as training data for generating a trained statistical model, as described throughout the disclosure. In some embodiments, a semiconductor test system may include a model. The model may be configured to receive, as input, wafer test data (and reduced versions thereof) and symbolic features, and provide, as output, groups of dies predicted to include failed final test dies. In some embodiments, the model may comprise a statistical model trained on training data for known or annotated failed final test dies.

Models described herein may be trained using supervised machine learning. Supervised machine learning may include providing labeled training data to a classifier and penalizing or rewarding the classifier depending on whether the classifier correctly classifies the training data. For example, training a classifier to classify images of objects labeled as red, blue, or green may include rewarding the classifier for correctly classifying a green-labeled image of grass as green, and penalizing the classifier for incorrectly classifying a red-labeled image of a firetruck as blue. Thus, the classifier may properly classify future image inputs and infer whether to classify the images as red, blue, or green. Accordingly input data may comprise labels indicating that the data is known to have similar characteristics, and/or different characteristics, in order to emphasize and/or de-emphasize the similar and/or different characteristics during training. During training of a model, weights and/or biases of the model may be adjusted to emphasize recognition of the particular characteristics of the training data. Supervised learning techniques may be useful for sorting new data into known categories, as in the image example.

Models described herein may also be trained using unsupervised machine leaning. Unsupervised machine learning may include providing unlabeled training data to an encoder which the encoder may sort into self-similar groups. For example, the same images provided to the classifier above may be provided to an encoder, which may map the images into a continuous space. In this example, the encoder may form clusters of similar images based on various perceived characteristics of the images, such as the color of the object in each image. However, unlike training the classifier, the encoder may take into account other characteristics of the input data, such as the shape of the objects in the images, and the encoder is not penalized for doing so in the manner described for the classifier. Accordingly, such encoders may be configured to group future inputs based on characteristics encountered during training. In some embodiments, models described herein may be trained using machine learning techniques that combine aspects of unsupervised and supervised machine learning.

In one such embodiment, a trained statistical model such as a neural network, or other appropriate statistical model, may be trained to output groups of dies predicted to include failed final test dies using the wafer test data (and reduced versions thereof) and symbolic features described herein as input to the trained statistical model. In one embodiment, some or all of the wafer test data (and reduced versions thereof) and symbolic features described herein, along with information identifying known groups of dies predicted to include failed final test dies as training data into a statistical model in a machine learning module. Once these inputs have been received, the machine learning module may generate a trained statistical model using the training data. The resulting output from the machine learning module may correspond to a model for groups of dies predicted to include failed final test dies, which is a trained statistical model of groups of dies predicted to include failed final test dies as a function of some or all of the types of the wafer test data (and reduced versions thereof) and symbolic features described herein. The trained statistical model may also be stored in an appropriate non-transitory computer readable medium for subsequent use as detailed further below.

It should be understood that the trained statistical models disclosed herein may be generated using any appropriate statistical model. For example, a machine learning module may correspond to any appropriate fitting method capable of generating the desired trained statistical models. It should also be understood that the above methods may be combined with any appropriate type of fitting approximation to provide a desired combination of model accuracy versus computational expense.

In general, a statistical model comprises a functional component designed and/or trained to analyze new inputs based on probabilistic patterns observed in prior training inputs. In this sense, statistical models differ from “rule-based” models, which typically apply hard-coded deterministic rules to map from inputs having particular characteristics to particular outputs. By contrast, a statistical model may operate to determine a particular output for an input with particular characteristics by considering how often (e.g., with what probability) training inputs with those same characteristics (or similar characteristics) were associated with that particular output in the statistical model's training data. To supply the probabilistic data that allows a statistical model to extrapolate from the tendency of particular input characteristics to be associated with particular outputs in past examples, statistical models are typically trained (or “built”) on large training corpuses with great numbers of example inputs. Typically, the example inputs may be labeled with the known outputs with which they should be associated, usually by a human labeler with expert knowledge of the domain. Characteristics of interest (known as “features”) are identified (“extracted”) from the inputs, and the statistical model learns the probabilities with which different features are associated with different outputs, based on how often training inputs with those features are associated with those outputs. When the same features are extracted from a new input (e.g., an input that has not been labeled with a known output by a human), the statistical model can then use the learned probabilities for the extracted features (as learned from the training data) to determine which output is most likely correct for the new input.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

Having described above several aspects of at least one embodiment, it is to be appreciated various alterations, modifications, and improvements will readily occur to those skilled in the art. Such alterations, modifications, and improvements are intended to be object of this disclosure. Accordingly, the foregoing description and drawings are by way of example only.

What is claimed is:

1. A method of semiconductor die final testing, comprising:
reducing, using at least one processor, dimensionality of wafer test data for one or more wafers, the one or more wafers having a first plurality of dies disposed thereon;
generating, using the at least one processor, a first plurality of die clusters of the first plurality of dies, using the dimensionally reduced wafer test data;
classifying, using the at least one processor, with a classification model, each die cluster of the first plurality of die clusters based on a likelihood of the die cluster including a failed die; and
refining, using the at least one processor, with a graphic model, the first plurality of die clusters into a second plurality of die clusters, the second plurality of die clusters being smaller than the first plurality of die clusters.

2. The method of claim 1, wherein:
the method further comprises receiving, using the at least one processor, the wafer test data for the one or more wafers, the wafer test data representing test results of functionality tests performed on the first plurality of dies;
reducing the dimensionality of the wafer test data for the one or more wafers comprises using principal component analysis to reduce the wafer test data to a set of principal components;
the method further comprises determining, using the at least one processor, one or more spatial scores for dies of the first plurality of dies, the one or more spatial scores including one or more of:
a first spatial score indicating a spatial position of a die on the one or more wafers; or
a second spatial score indicating failures of dies neighboring a die;
generating the first plurality of die clusters of the first plurality of dies using the dimensionally reduced wafer test data comprises clustering the first plurality of dies into the first plurality of die clusters based on the set of principal components and the one or more spatial scores;
classifying, with the classification model, each die cluster of the first plurality of die clusters based on the likelihood of the die cluster including a failed die comprises labeling each die cluster of the first plurality of die clusters with a die failure label selected from a plurality of die failure labels, the plurality of die failure labels including:
a first die failure label indicating a first likelihood of a die cluster including a failed die; and
a second die failure label indicating a second likelihood of a die cluster including a failed die, the second likelihood higher than the first likelihood;
refining, with the graphic model, the first plurality of die clusters into the second plurality of die clusters comprises:
selecting a second plurality of dies from the first plurality of dies by excluding, from the second plurality of dies, die clusters of the first plurality of die clusters having the first die failure label;
re-clustering the second plurality of dies into the second plurality of die clusters; and
the method further comprises selecting, using the at least one processor, at least some dies of the second plurality of dies as candidates for additional testing, based on the second plurality of die clusters.

3. The method of claim 2, further comprising, prior to collecting the wafer test data for the one or more wafers, fabricating the one or more wafers having the first plurality of dies disposed thereon.

4. The method of claim 2, further comprising performing final testing on the at least some dies of the second plurality of dies comprising the candidates.

5. The method of claim 2, wherein reducing the wafer test data to a set of principal components comprises reducing dimensionality of the wafer test data to the set of principal components based on variation of the wafer test data.

6. The method of claim 2, wherein determining one or more spatial scores for dies of the first plurality of dies comprises:
generating the first spatial score as an edge proximity score indicating distance from a die to a nearest edge of a wafer upon which the die is disposed; and
generating the second spatial score as a neighborhood score indicating failures of dies neighboring a die, the failures being weighted based on a distance from the die to failed dies.

7. The method of claim 2, wherein clustering, using the at least one processor, the first plurality of dies into a first plurality of die clusters based on the set of principal components and the one or more spatial scores comprises moving dies between clusters based on a minimum cluster size and a maximum cluster size.

8. The method of claim 2, further comprising:
labeling, using the at least one processor, each die cluster of the second plurality of die clusters with a die failure label selected from the plurality of die failure labels;
selecting, using the at least one processor, a third plurality of dies from the second plurality of dies by excluding, from the third plurality of dies, die clusters of the second plurality of die clusters having the first die failure label; and
re-clustering, using the at least one processor, the third plurality of dies into a third plurality of die clusters, an average size of the third plurality of die clusters being smaller than an average size of the second plurality of die clusters.

9. At least one non-transitory computer-readable storage medium having instructions encoded thereon that, when executed by at least one processor, cause the at least one processor to perform a method of semiconductor die final testing, the method comprising:
reducing dimensionality of wafer test data for one or more wafers, the one or more wafers having a first plurality of dies disposed thereon;
generating a first plurality of die clusters of the first plurality of dies, using the dimensionally reduced wafer test data;
classifying, with a classification model, each die cluster of the first plurality of die clusters based on a likelihood of the die cluster including a failed die; and
refining, with a graphic model, the first plurality of die clusters into a second plurality of die clusters, the second plurality of die clusters being smaller than the first plurality of die clusters.

10. The at least one non-transitory computer-readable storage medium of claim 9, wherein:
the method further comprises receiving the wafer test data for the one or more wafers, the wafer test data representing test results of functionality tests performed on the first plurality of dies;
reducing the dimensionality of the wafer test data for the one or more wafers comprises using principal component analysis to reduce the wafer test data to a set of principal components;
the method further comprises determining one or more spatial scores for dies of the first plurality of dies, the one or more spatial scores including one or more of:
a first spatial score indicating a spatial position of a die on the one or more wafers; or
a second spatial score indicating failures of dies neighboring a die;
generating the first plurality of die clusters of the first plurality of dies using the dimensionally reduced wafer test data comprises clustering the first plurality of dies into the first plurality of die clusters based on the set of principal components and the one or more spatial scores;
classifying, with the classification model, each die cluster of the first plurality of die clusters based on the likelihood of the die cluster including a failed die comprises labeling each die cluster of the first plurality of die clusters with a die failure label selected from a plurality of die failure labels, the plurality of die failure labels including:
a first die failure label indicating a first likelihood of a die cluster including a failed die; and
a second die failure label indicating a second likelihood of a die cluster including a failed die, the second likelihood higher than the first likelihood;
refining, with the graphic model, the first plurality of die clusters into the second plurality of die clusters comprises:
selecting a second plurality of dies from the first plurality of dies by excluding, from the second plurality of dies, die clusters of the first plurality of die clusters having the first die failure label;
re-clustering the second plurality of dies into the second plurality of die clusters; and
the method further comprises selecting at least some dies of the second plurality of dies as candidates for additional testing, based on the second plurality of die clusters.

11. The at least one non-transitory computer-readable storage medium of claim 10, wherein the method further comprises, prior to collecting the wafer test data for the one or more wafers, fabricating the one or more wafers having the first plurality of dies disposed thereon.

12. The at least one non-transitory computer-readable storage medium of claim 10, wherein the method further comprises performing final testing on the at least some dies of the second plurality of dies comprising the candidates.

13. The at least one non-transitory computer-readable storage medium of claim 10, wherein reducing the wafer test data to a set of principal components comprises reducing dimensionality of the wafer test data to the set of principal components based on variation of the wafer test data.

14. The at least one non-transitory computer-readable storage medium of claim 10, wherein determining one or more spatial scores for dies of the first plurality of dies comprises:
generating the first spatial score as an edge proximity score indicating distance from a die to a nearest edge of a wafer upon which the die is disposed; and
generating the second spatial score as a neighborhood score indicating failures of dies neighboring a die, the failures being weighted based on a distance from the die to failed dies.

15. The at least one non-transitory computer-readable storage medium of claim 10, wherein clustering the first plurality of dies into a first plurality of die clusters based on the set of principal components and the one or more spatial scores comprises moving dies between clusters based on a minimum cluster size and a maximum cluster size.

16. The at least one non-transitory computer-readable storage medium of claim 10, wherein the method further comprises:
labeling each die cluster of the second plurality of die clusters with a die failure label selected from the plurality of die failure labels;
selecting a third plurality of dies from the second plurality of dies by excluding, from the third plurality of dies, die clusters of the second plurality of die clusters having the first die failure label; and
re-clustering the third plurality of dies into a third plurality of die clusters, an average size of the third plurality of die clusters being smaller than an average size of the second plurality of die clusters.

17. A semiconductor wafer test system comprising:
at least one processor; and
at least one non-transitory computer-readable storage medium having instructions encoded thereon that, when executed by the at least one processor, cause the at least one processor to perform a method comprising:
reducing dimensionality of wafer test data for one or more wafers, the one or more wafers having a first plurality of dies disposed thereon;
generating a first plurality of die clusters of the first plurality of dies, using the dimensionally reduced wafer test data;
classifying, with a classification model, each die cluster of the first plurality of die clusters based on a likelihood of the die cluster including a failed die; and
refining, with a graphic model, the first plurality of die clusters into a second plurality of die clusters, the second plurality of die clusters being smaller than the first plurality of die clusters.

18. The semiconductor wafer test system of claim 17, wherein:
the semiconductor wafer test system further comprises at least one semiconductor test probe configured to collect the wafer test data for the one or more wafers, the wafer test data representing test results of functionality tests performed on the first plurality of dies;
reducing the dimensionality of the wafer test data for the one or more wafers comprises using principal component analysis to reduce the wafer test data to a set of principal components;
the method further comprises determining one or more spatial scores for dies of the first plurality of dies, the one or more spatial scores including one or more of:
a first spatial score indicating a spatial position of a die on the one or more wafers; or
a second spatial score indicating failures of dies neighboring a die;
generating the first plurality of die clusters of the first plurality of dies using the dimensionally reduced wafer test data comprises clustering the first plurality of dies into the first plurality of die clusters based on the set of principal components and the one or more spatial scores;
classifying, with the classification model, each die cluster of the first plurality of die clusters based on the likelihood of the die cluster including a failed die comprises labeling each die cluster of the first plurality of die clusters with a die failure label selected from a plurality of die failure labels, the plurality of die failure labels including:
a first die failure label indicating a first likelihood of a die cluster including a failed die; and
a second die failure label indicating a second likelihood of a die cluster including a failed die, the second likelihood higher than the first likelihood;
refining, with the graphic model, the first plurality of die clusters into the second plurality of die clusters comprises:
selecting a second plurality of dies from the first plurality of dies by excluding, from the second plurality of dies, die clusters of the first plurality of die clusters having the first die failure label;
re-clustering the second plurality of dies into the second plurality of die clusters; and
the method further comprises selecting at least some dies of the second plurality of dies as candidates for additional testing, based on the second plurality of die clusters.

19. The semiconductor wafer test system of claim 18, wherein the at least one semiconductor test probe is further configured to perform final testing on the at least some dies of the second plurality of dies comprising the candidates.

20. The semiconductor wafer test system of claim 18, wherein reducing the wafer test data to a set of principal components comprises reducing dimensionality of the wafer test data to the set of principal components based on variation of the wafer test data.

21. The semiconductor wafer test system of claim 18, wherein determining one or more spatial scores for dies of the first plurality of dies comprises:
generating the first spatial score as an edge proximity score indicating distance from a die to a nearest edge of a wafer upon which the die is disposed; and
generating the second spatial score as a neighborhood score indicating failures of dies neighboring a die, the failures being weighted based on a distance from the die to failed dies.

22. The semiconductor wafer test system of claim 18, wherein clustering the first plurality of dies into a first plurality of die clusters based on the set of principal components and the one or more spatial scores comprises moving dies between clusters based on a minimum cluster size and a maximum cluster size.

23. The semiconductor wafer test system of claim 18, wherein the method further comprises:
labeling each die cluster of the second plurality of die clusters with a die failure label selected from the plurality of die failure labels;
selecting a third plurality of dies from the second plurality of dies by excluding, from the third plurality of dies, die clusters of the second plurality of die clusters having the first die failure label; and
re-clustering the third plurality of dies into a third plurality of die clusters, an average size of the third plurality of die clusters being smaller than an average size of the second plurality of die clusters.
